(19) United States
(12) Patent Application Publication
(10) Pub. No.: US 2005/0124304 A1
(43) Pub. Date: Jun. 9, 2005

(54) TV & FM transmitting system early warning monitoring

(76) Inventor: Oded Bendov, Cherry Hill, NJ (US)

Correspondence Address: DUANE MORRIS LLP, PO BOX 5203, PRINCETON, NJ, 08543-5203, US

(21) Appl. No.: 10/910,905

(22) Filed: Aug. 4, 2004

Related U.S. Application Data
(60) Provisional application No. 60/528,050, filed on Dec. 9, 2003.

(51) Int. Cl. H03C 1/62; H04B 17/00; H04B 1/04; H01Q 11/12

(52) U.S. Cl. 455/115.1; 455/117; 455/129

(57) ABSTRACT

A computerized monitoring apparatus processes signals representing (a) incident power I² to an antenna, (b) reflected power R², radiated power T², and arc voltage power A². The monitor provides warning of arcing or overheating in the feedlines to (and inside) the antenna before catastrophic failure. Early warning of developing failures allows for orderly transition to standby transmission and avoids losing on-air time. The monitoring apparatus also provides a failsafe indication of whether power is delivered to the antenna and whether the antenna radiates the power delivered to it. Such failsafe indication is required before personnel are allowed near the antenna. The apparatus measures the relative power density at specified locations near and on the tower, and compares the measured RFR exposure density to that allowable by the Federal Communications Commission. The monitoring apparatus can be applied to multiple transmitters with multiple channel combiners feeding a common antenna connection.

### CROSS REFERENCE TO RELATED APPLICATIONS

This application relates to and claims the benefit of the earlier filing date under 35 U.S.C. 119, of U.S. Provisional Patent Application Ser. No. 60/528,050 entitled “EARLY WARNING MONITORING METHOD, SYSTEM AND APPARATUS FOR TELEVISION AND FM RADIO TRANSMITTING ANTENNAS AND COAXIAL FEEDLINES,” filed on Dec. 9, 2003.

### FIELD OF THE INVENTION

This invention relates to the monitoring of electromagnetic transmitting arrangements for fault identification and/or safety.

### BACKGROUND OF THE INVENTION

Television and FM electromagnetic signals are radiated from transmitting systems which ordinarily include an electrical signal generator or transmitter, which produces signals modulated by the desired audio and/or video program, and possibly by data in some situations. The transmitter produces signals which become available as guided waves at a transmission-line port of the transmitter. In order to generate radiated or unguided electromagnetic signals, the guided waves must be transduced into unguided form. The device which is used to transduce guided electrical signals into unguided radiation is known as an antenna.

In order to obtain the broadest possible coverage of the radiated TV or FM signals, the antenna is often placed at a high and exposed location. Even at such locations, the antenna may be placed on a tower to increase its effective height; towers may have a height of as much as 2000 feet above ground level. The transmitter is often bulky and heavy, and cannot economically be placed at the top of the tower. Consequently, a wave guide or “transmission line” arrangement is coupled between the transmitter at a location near the base of the tower and the antenna, for coupling the guided waves to the antenna with low loss.

There are many types of transmission lines, which are generally divided into “balanced” and “unbalanced” types. An important property of transmission lines for many uses is that of signal propagation from one location to another with low loss. In general, a transmission line may “lose” signal power propagating along its length by ohmic or heat losses, by radiation, and by reflection of the signal back toward the source. Balanced transmission lines tend to be strongly affected by their environment, and may exhibit substantial losses by direct radiation. Consequently, balanced transmission lines are not often used for transmitter systems, and unbalanced transmission lines, such as coaxial transmission lines, are preferred. A coaxial transmission line includes an outer conductor surrounding, but not in contact with, an inner conductor. Ohmic or heating losses in coaxial transmission lines are generally addressed by selection of relatively large conductors, and also by use of low-loss dielectric materials for filling the region between the center and outer conductors. In some cases, the coaxial transmission line extending from the transmitter to the antenna may be pressurized with an inert gas or dry air.

Reflection losses in transmission lines are generally attributable to discontinuities in the surge or characteristic impedance of the transmission line. In theory, there should be no discontinuities, but the relatively conductors required for television and FM broadcast applications are sufficiently large that they must be fabricated and installed in sections. While efforts are made to reduce discontinuities at the junction of sections, they may still arise due to movement or corrosion of the joints, or at any location from damage.

A property of transmission lines is that the peak voltages which are experienced during operation may be increased by the presence of reflective discontinuities. Thus, peak voltages greater than those experienced during normal operation may occur at discontinuities in the transmission line carrying signals between a transmitter and an antenna, or at locations remote from the discontinuity. These voltages may be great enough to initiate arcing inside the unbalanced transmission line. Such arcing tends to erode or destroy the transmission line conductors in its vicinity. Overheating or arcing may be caused by the entry of moisture into the transmission line, which provides a path which increases the probability of arcing across those insulators that maintain the position of the center conductor relative to the outer conductor. The arcing tends to carbonize the insulators, thereby causing undesired dissipation of a portion of the transmitter power in the insulators. Excessive dissipation of power inside the feed transmission lines (feedlines) is a precursor of catastrophic failure. Other causes of catastrophic failure include excessive sway of the tower and excessive movement of the inner conductor relative to the outer conductor, possibly attributable to internal or external temperature variations. Once initiated, arcing and overheating may persist over weeks or months before a catastrophic failure occurs. The cost of replacement equipment and lost advertising revenue due to off-air time related to the failure may be substantial. Thus, a slight discontinuity in a transmission line may over time develop arcing and major damage at the location of the arc, and the damage may propagate along the transmission line. As the damage attributable to the signal reflections and arcing increases, failure of the transmission line may occur. Transmitters are generally provided with protection circuits which reduce the transmitted power or turn the transmitter off in the event of large signal reflections. By the time there are sufficient reflections to trigger the transmitter protection circuits, substantial damage or catastrophic damage may already have been inflicted on the transmission line or antenna. A catastrophic failure is evidenced by burnout within the power delivery system. Such burnouts can extend over as much as several hundred feet of feed transmission line, depending upon the sensitivity of the transmitter shut-down system and the speed with which it responds to overheating or arcing. While the burnout is in progress, the transmitter continues to deliver power to maintain the burnout process. At some later time, when the damage due to burnout has reached some level, the transmitter protective circuits sense the reflected power and automatically shut down the transmitter.

Improved or alternative transmitter system monitoring and alarm methods and or apparatus are desired.

### SUMMARY OF THE INVENTION

A method according to an aspect of the invention for transmitter control in an electromagnetic wave transmitting system which includes a transmitter coupled by a first transmission line to an antenna comprises the steps of sensing the presence of arcing in the first transmission line and generating a signal in the presence of the arcing. The method also includes the step of reducing the power transmitted by the transmitter in the presence of the signal. The method may also include the step of transmitting signal from the transmitter toward the antenna through the transmission line within a predetermined frequency band, in which case the step of sensing the presence of arcing in the first transmission line includes the step of low-pass filtering signal appearing on the transmission line, to thereby block signals within the predetermined frequency band and to pass only frequencies lower than those of the predetermined frequency band. In a particularly advantageous mode of this aspect of the invention, the step of sensing the presence of arcing and generating a signal includes the steps of determining the ratios of K₀ and K(t), where

$${K}_{0} = {( \frac{{R}_{0}}{{T}_{0}} )}^{2} and K ( t ) = {( \frac{R ( t )}{T ( t )} )}^{2} \qquad ( 2 )$$

are the ratios during normal operation and during a failure in progress, respectively, and wherein
R₀ is the reflected signal voltage during normal operation;
R(t) is the reflected signal voltage during a failure in progress;
T₀ is the transmitted signal voltage during normal operation; and
T(t) is the transmitted signal voltage during a failure in progress. The step of generating a signal also includes the step of generating an alarm signal if

$$\frac{K ( t )}{{K}_{0}} 〉 1. \qquad ( 3 )$$

According to another aspect of the invention, a method for failure detection in an electromagnetic wave transmitting system which includes a transmitter coupled by a first transmission line to an antenna comprises the steps of sensing the radiated power from the antenna by use of a receiving antenna, and comparing with a standard representative of proper operation of the transmitting system at least one of (a) the received radiated power and (b) the ratio of incident to reflected power, to thereby generate a first signal. Arcing in the first transmission line is sensed and a second signal is generated in the presence of arcing. A failure-indicative signal is generated in the presence of at least one of the first and second signals. In this other aspect of the invention, the step of sensing arcing in the transmission line may include the steps of coupling a first end of a second transmission line in electrical parallel with the first transmission line, where the second transmission line is one of short-circuited and open-circuited at that end remote from the first end. The second transmission line may define a tap at a location which is located an integer number of half-wavelengths from that end remote from the first end in the case of a short-circuit termination and an odd integer number of quarter-wavelengths from that end remote from the first end in the case of an open-circuit termination. In this other aspect of the invention, the transmission line may be an unbalanced transmission line including an elongated conductor having a given surface area and a second conductor having a surface area larger than the given surface area; the step of sensing arcing in the transmission line in this case includes the steps of extending an insulated conductor physically parallel with the elongated and second conductors and spaced therefrom, and coupling voltage appearing on the insulated conductor to a location outside the transmission line.

According to yet another aspect of the invention, an apparatus includes an antenna for one of television and FM, with the antenna including an unbalanced transmission-line input port, and a source of transmitter power for the one of television and FM. An unbalanced feed transmission-line is coupled to the input port of the antenna, for coupling power originating from the source to the antenna for generating electromagnetic radiation therefrom. A receiving antenna is provided for receiving the electromagnetic radiation, and for generating an analog signal indicative of the power transmitted by the antenna. A directional coupling arrangement is coupled to the feed transmission-line for generating analog signals indicative of signal power incident on the feed transmission line from the source and of reflected power reflected from the antenna toward the source. A power measurement arrangement is coupled to receive the analog signals indicative of transmitted, incident, and reflected power, for generating analog signals representative of transmitted, incident, and reflected power, respectively. An analog-to-digital conversion arrangement is coupled to receive analog signals representative of transmitted, incident, and reflected power, for converting the analog signals into digital signals representative of measured transmitted, incident, and reflected power. A processing arrangement is coupled to receive the digital signals, and for comparing the measured transmitted, incident, and reflected power with stored reference values of the transmitted, incident, and reflected power, and for generating alarm signals in response, which may be monotonic response, to deviation of the measured power relative to or with respect to the reference values. This apparatus may include filtering means for filtering the analog signals. It may also include a switching arrangement coupled to the receiving antenna, to the directional coupling arrangement, and to the analog-to-digital conversion arrangement, for sequentially switching the analog signals representing transmitted power, incident power, and reflected power to the analog-to-digital conversion means in the form of pulse-amplitude-modulated signals. The processing arrangement may comprise a network connection arrangement for providing remote control of the processing means by way of at least one of (a) landline telephone, (b) wireless telephone, and (c) World Wide Web.

A method according to a yet further aspect of the invention for transmitter control in an electromagnetic wave transmitting system, which transmitting system includes a transmitter coupled by a first transmission line to an antenna, comprises the steps of, during normal operation, determining the signal voltage or amplitude reflected from the antenna toward the transmitter in the first transmission line and the transmitted signal amplitude or voltage, and storing information relating to the normal-operation reflected and transmitted signal voltage or amplitude. The current signal voltage reflected from the antenna toward the transmitter in the first transmission line, and the transmitted signal amplitude, are monitored, to thereby form current reflected and transmitted signal voltage or amplitude information. A constant K₀ is determined by squaring the quotient of the normal-operation reflected signal voltage divided by the normal-operation transmitted signal amplitude. A further constant K(t) is determined by squaring the quotient of the current reflected signal voltage divided by the current transmitted signal amplitude. The presence of arcing in the first transmission line is sensed or determined by taking the ratio of K(t) divided by K₀, and deeming arcing to be present if

$$\frac{K ( t )}{{K}_{0}} 〉 1.$$

In a preferred version of this aspect of the invention, an alarm signal is generated when arcing is deemed to be present.

A method for exposure control in a system of plural transmitting antennas fed by transmission lines according to another aspect of the invention comprises the steps of sensing the transmitted power from each of the antennas to produce individual antenna powers, and summing the individual antenna powers to produce a summed-transmitted-power signal. The method also includes the step of measuring incident power flowing in the transmission lines to each of the antennas, and summing the incident power for each of the antennas to produce a summed incident power signal. Climbing on any of the antennas is prohibited so long as one of the summed-transmitted-power signal and the summed incident power signal has a value exceeding zero.

A method for exposure control in an electromagnetic transmitter arrangement according to a further aspect of the invention includes the steps of sensing transmitted signal voltage during normal operation and sensing the current transmitted voltage, and squaring the ratio of the current transmitted voltage divided by the normal-operation signal voltage to produce a calculated result. This method also includes the comparing of the calculated result with the FCC allowable RFR (Radiofrequency Radiation) exposure limit, and setting an exposure alarm if the calculated result exceeds the FCC allowable RFR exposure limit.

### BRIEF DESCRIPTION OF THE DRAWING

FIG. 1 is a simplified block diagram of a single-channel monitoring system according to an aspect of the invention;

FIG. 2 is a simplified block diagram of a multiplexed-channel monitoring system according to another aspect of the invention;

FIG. 3a is a simplified cross-sectional view of a broadband arcing detection probe according to an aspect of the invention which may be used in the arrangement of FIG. 2, and FIG. 3b is a transverse cross-section thereof; and

FIG. 4a is a simplified cross-sectional, view of a single-channel arcing detection probe which may be used in the arrangement of FIG. 1, and FIG. 4b is a detail.

### DESCRIPTION OF THE INVENTION

Prior to the present invention there have been no systems and methods that would provide reliable early warning of arcing or overheating in TV and FM broadcast antennas and in their feedlines. Prior to the present invention, failure reporting methods have been based solely on measuring the power (or voltage) being reflected back toward the transmitter, sometimes together with measurement of the loss of gas pressure inside the feedlines. Those methods provided protection for the transmitter from reflected power, but did not prevent the transmitter from continuing to supply power to the overheating or arcing areas inside the feedlines until after the burnout was almost complete. That occurred because, while power would be supplied to the failing areas, only a small portion of it, if any at all, would be reflected back, and might not be sensed. Consequently, the damage might continue to increase until a catastrophic failure materialized. Only at times near or after catastrophic failure would a significant portion of the power intended for the antenna be reflected back toward the transmitter, tripping the transmitter's protective circuit and thereby causing the transmitter to shut down.

The present invention provides an effective means for early warning resulting from overheating or arcing in the coaxial feedlines of broadcast antennas for TV and FM radio. It does so, in general, by simultaneously monitoring for arcing inside the coaxial feedlines and for changes in the level of power radiated by the antenna (or dissipated in the feedlines). The monitored levels are continuously compared with the expected (nominal) levels of lost power in the feedlines and the level of power reflected back toward the transmitter during normal operation. Unexpected deviations from nominal power levels are treated as alarms.

The present invention also provides for a failsafe determination of which antenna is radiating within a complex of several antennas, and also for a determination of the power density level emanating from each radiating antenna at specified locations on the ground or on the tower. Such monitoring allows the broadcaster to ensure compliance with FCC regulations and also to protect maintenance personnel and the general public from excessive Radio Frequency (RF) exposure.

In general, the monitored power levels are collected by up to four probes per TV or FM channel and are processed with the aid of a local computer that translates the processed signals into alarms. One of the four probes is a consumer-grade rooftop antenna. This antenna would typically be mounted on the roof of the transmitter building. The output power available from that rooftop antenna is proportional to the radiated power. Thus, any loss of power intended for delivery to the transmitting antenna would be either in the form of lost radiated power or increase on the power reflected back toward the transmitter. The consumer-grade antenna would detect loss of radiated power, while a directional coupler on the feedline to the transmitting antenna would detect the rise of reflected power.

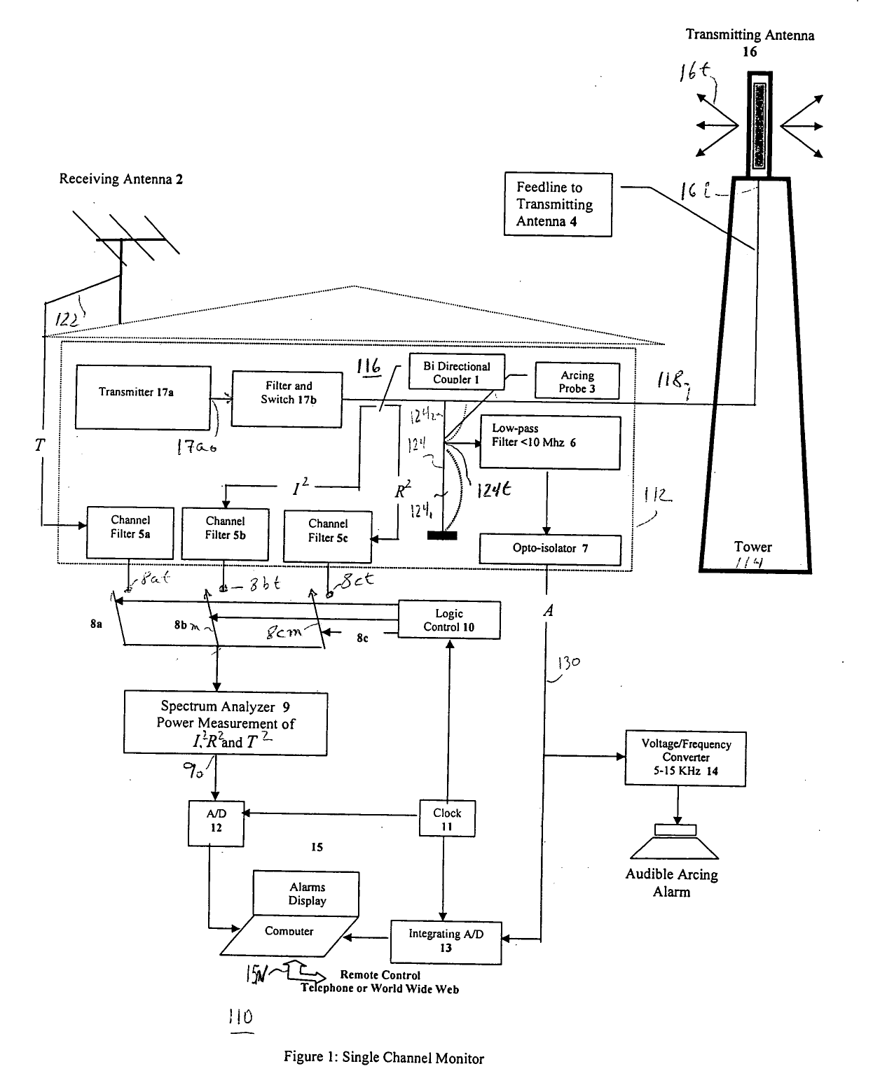

In FIG. 1, a single-channel transmitter system 110 includes a single-channel transmitter 17a located in a building or housing 112. In this context, “single-channel” has the meaning of limitation of the signal bandwidth to occupy only one standard frequency band allocation, as 200 KHz for FM or 6 MHz for television. A transmitting antenna 16 is mounted at the top of a tower 114. Transmitter 17a includes a transmission-line output port 17ao which is coupled by an unbalanced transmission-line path designated generally as 116 to a transmission-line input port 16i of antenna 16. Transmission line path 116 includes a filter and switch illustrated as a block 17b, a bi-directional coupler or pair of directional couplers 1, and a coaxial transmission line 118, and is also associated with an arcing probe 3.

Directional coupler 1 samples the incident signal power (I²) applied to the directional coupler from filter and switch 17b, and also samples the reflected signal power (R²) returning to directional coupler 1 from coaxial transmission line 118. The sample of incident power I² is coupled to a channel filter 5b, which allows I² signal within the channel bandwidth to pass to a terminal 8bt of switch portion 8b. The sample of reflected power R² is coupled to a channel filter 5c, which allows R² signal within the channel bandwidth to pass to a terminal 8ct of switch portion 8c. The probes for the incident I² and reflected R² power can be two independent directional couplers or a single bidirectional coupler. Both types are standard equipment normally supplied as part of the transmitter system equipment. Note that, if a bidirectional coupler is used rather than two separate directional couplers, only three probes, namely the bidirectional coupler, the receiving antenna, and the arcing detector are required to provide four sensed parameters.

System 110 of FIG. 1 also illustrates a receiving antenna 2 which is oriented to receive radiated or transmitted signals 16t from transmitting antenna 16, and transducing them into guided-wave form flowing in a transmission line 122 to a channel filter 5a. The received signals are proportional to the transmitted power T². Receiving antenna 2 may be a simple consumer-grade or home TV antenna, preferably channelized, but it may be broadband. Channel filter 5a allows only the signals on the selected channel to flow to a terminal 8 at of a switch 8a. It should be noted that switches 8a, 8b, and 8c are represented in FIG. 1 by conventional mechanical switch symbols, but those skilled in the art know that this representation is solely for explanatory purposes. In actuality, controllable electronic switches are used rather than mechanical switches.

In the arrangement of FIG. 1, switches 8a, 8b, and 8c are actuated by a logic control circuit illustrated as a block 10. Logic control block 10, in turn, is controlled by at least a clock circuit 11, and possibly by a computer illustrated as 15. Switches 8a, 8b, and 8c are actuated in turn or in sequence, thereby sequentially allowing the filtered T² signal from channel filter 5a, the filtered I² signal from channel filter 5b, or the filtered R² signal from channel filter 5c to be coupled to a power-measuring instrument such as a spectrum analyzer. The analog signals are in Pulse Amplitude Modulation (PAM) form after the switching. Power measuring block or spectrum analyzer 9 to produces signals at an analog output port 9o which represent the power of the PAM signals applied to its input. The analog signals from output port 9o of power-measuring instrument 9 are applied to an analog-to-digital converter (A/D or ADC) 12 for conversion into digital form for use by computer 15. As an alternative, the spectrum analyzer itself may perform the conversion of the signals into digital form.

The output power available from rooftop antenna 2 is proportional to the power T² of the radiated signal 16t from transmitting antenna 16. Thus, any loss of power intended for delivery to the transmitting antenna 16 would be either in the form of lost radiated power 16t or an increase on the power reflected back toward the transmitter. The consumer-grade antenna 2 detects loss of radiated power and directional coupler 116 on the feed transmission line 118 to the transmitting antenna 16 detects the rise of reflected power. For the present description of the method it can be assumed that the nominal loss of power prior to the onset of failure of the transmission line 118 is zero and therefore that the equation governing the relationship among incident I², reflected R² and radiated T² power is:

$${( \frac{T}{R} )}^{2} = {( \frac{I}{R} )}^{2} - 1 \qquad ( 1 )$$

Thus, if the values of R² and I² are known from calibrated measurements, the ratio (T/R)² will decrease during arcing or overheating as a result of an arc if either the reflected power increases or the radiated power decreases. During arcing or overheating, the reflected power can only increase and the radiated power can only decrease relative to the condition before the arcing or overheating. Prior to the onset of failure of the transmission line 118, the ratio (T/R)² is independent of the power delivered by the transmitter 17a. Therefore, the ratio of (T/R)² can serve as a failure metric regardless of the transmitter's operating power. More specifically, if

$${K}_{0} = {( \frac{{R}_{0}}{{T}_{0}} )}^{2} and K ( t ) = {( \frac{R ( t )}{T ( t )} )}^{2} \qquad ( 2 )$$

are the ratios during normal operation and during a failure in progress, respectively, then arcing or overheating alarm would be indicated if

$$\frac{K ( t )}{{K}_{0}} 〉 1 \qquad ( 3 )$$

As mentioned, the probes for the incident I² and reflected R² powers can be independent directional couplers or a single bidirectional coupler. During installation of the transmitter 110 equipment, the incident power I², the reflected power R² are calibrated so that R₀², I₀², and thus K₀ are known.

During normal operation, the radio-frequency (RF) signal exposure levels are monitored or measured at several locations on and around the tower 114 of FIG. 1. The measured levels are proportional to the radiated or transmitted power T₀². Any variation in T₀² is likely to translate into proportional change in the previously measured or calibrated exposure levels. Exposure alarm is indicated if the transmitted power T²(t) at locations accessible by maintenance personnel is

$${( \frac{T ( t )}{{T}_{0}} )}^{2} \leq FCC Allowable RFR Exposure Limit \qquad ( 4 )$$

where (t) indicates that the calculated or measured variable is a function of time and the RFR (Radiofrequency Radiation) exposure limit is defined in the FCC's Bulletin OET-65. Climbing on the antenna would be prohibited so long as, for any channel, radiation from the antenna T²(t)>0 or I²>0. For N antennas all within proximity of each other, climbing would be permitted only if
T₁²+T₂²+T₃²+ . . . , T_{N}²=0 (5)
and
I₁²+I₂²+I₃²+ . . . I_{N}²=0 (6)

The arcing phenomenon produces irregular pulses of electromagnetic radiation, visible flashes, and ozone gas. An aspect of the present invention detects the electromagnetic pulses produced by arcing. The most significant frequencies contained in these pulses, namely those carrying the most power, are below 10 MHz. Because of the low frequencies, most TV and FM antennas are unable to radiate the power produced by arcing. Thus, the electromagnetic energy created by arcing remains confined within the coaxial transmission lines extending between the antenna at one end and the filter/switcher associated with the transmitter at the other end.

Arcing probe 3 of FIG. 1 is connected to transmission line 118 at a location between filter and switch 17b and the antenna 16. In the single-channel case illustrated in FIG. 1, the arcing probe includes, in principle, a further transmission line 124, consisting of a first portion 124₁ and a second portion 124₂, coupled in shunt or in electrical parallel to transmission line 118, and with its end remote from the shunt connection terminated in either an open- or short-circuit reactive termination. In general, a short-circuit is preferred. A tap 124t is connected to the further transmission line 124 at the junction of transmission line portions 124₁ and 124₂. The tap 124t is at a location along the length of transmission line 124 which is an integer number of quarter-wavelengths from the reactive termination. In the case of an open-circuit reactive termination, the tap point is an odd number of quarter-wavelengths from the reactive termination, and in the case of the short-circuit reactive termination, the tap is located at an even number of quarter-wavelengths therefrom. Those skilled in the art know that the impedance one-half wavelength from a short-circuit in a transmission line appears as a short circuit, and the impedance one-quarter wavelength from an open circuit also appears as a short circuit. Consequently, any signal at the channel frequency appearing at tap point 124t appears “across” a short-circuit, and produces no voltage. Those skilled in the art also know that terms such as “across” and “between” have different meanings in electrical contexts than in mechanical or topological contexts. Since the effective impedance at tap point 124t is zero, the tap impedance must be isolated from transmission line 118. The isolation is provided by making the electrical length of shunt transmission line portion 124₂ equal to one-quarter wavelength at the channel frequency. In the case illustrated in FIG. 1, the shunt transmission line 124 is represented as being connected to ground or short-circuited, so at least two quarter-wavelengths or one half-wavelength separate the termination and the tap point 124t. The purpose of this arrangement of transmission lines is to prevent in-channel signals from being coupled from transmission line 118 to the arc sensing circuits including low-pass filter 6, opto-isolator 7, and integrating A/D 13, and to allow low-frequency signals to be coupled to the arc sensing circuits. It should be noted that the arc sensing probe 3 must be located in the transmission line “between” the antenna 16 and filter and switch block 17b rather than between the transmitter 17a and the filter and switch block 17b, because little, if any, arcing power will pass back through the filter and switch block 17b toward the transmitter 17a.

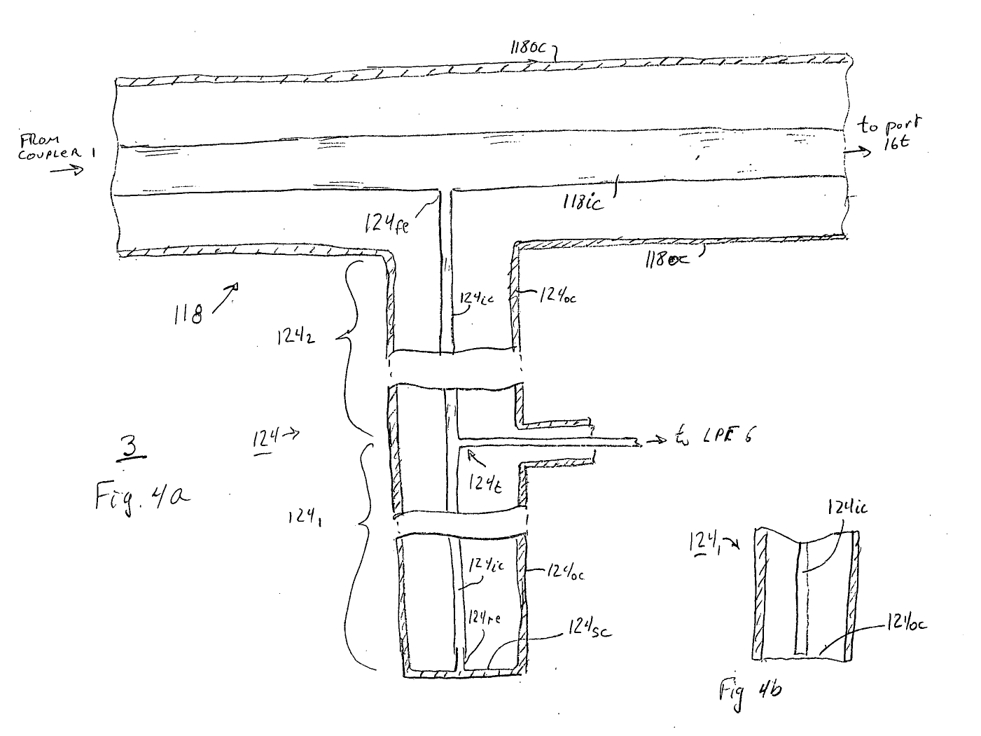

FIG. 4a illustrates further details of the structure of arcing probe 3 of FIG. 1. In FIG. 4a, the outer conductor of transmission line 118 is illustrated as 118oc and the inner conductor is designated 118ic. The outer conductor of shunt transmission line 124 is designated 124oc and the inner conductor is designated 124ic. Inner conductor 124ic makes contact with inner conductor 118ic at a first end 124fe. The tap point 124t lies between shunt transmission line sections or segments 124₁ and 124₂. That end 124re of transmission line 24 remote from the first end 124fe is terminated. In FIG. 4a, the termination at end 124re is a short circuit 124sc. FIG. 4b illustrates a portion of transmission line 124₁ adjacent the termination, where the termination is an open circuit 124oc rather than a short circuit 124sc as in FIG. 4a.

An electrical arc is a broadband noise generator. When the arc occurs between the conductors of a transmission line, the broadband noise propagates away from the location of the arc in both directions along the transmission line. That portion of the broadband noise propagating toward the antenna cannot, in general, be radiated, because the antenna is tuned to the channel frequency. Additionally, the broadband noise cannot propagate backwards through the filter associated with block 17b of FIG. 1. Thus, a major portion of the voltage associated with the noise attributable to the arc becomes available at tap 124t, and the low-frequency components are coupled through low-pass filter 6 to an opto-isolator 7. Opto-isolator 7 provides an optical isolation path between the relatively high voltages found in the transmission lines and the relatively low voltages required for signal processing. Thus, opto-isolator 7 produces on a path 130 an amplitude signal A representing the amplitude of the arc noise, but without coupling large voltages to path 130. In the absence of an arc, the noise should be low, while in the presence of an arc, an analog signal related to the amplitude A of the arc will appear on path 130. The arc amplitude related signal A is applied to an integrating A/D converter 13 for conversion into digital form useful to computer 15. Once arcing or overheating alarm is triggered by the processing associated with computer 15, the incident power I² is lowered, manually or automatically by the computer, until K(t)/K₀≧1 or until the arcing alarm ceases. The control computer 15 may be operated by remote control, as for example over telephone or the World Wide Web.

As illustrated in FIG. 1, the arc amplitude related signal A appearing on signal path 130 can be coupled to a voltage-to-frequency converter illustrated as a block 14. Low arc voltages are converted to low audio frequencies, while large arc voltages are converted into high audio frequencies. The largest arc amplitudes result in signals at frequencies near 15 KHz. These signals may be applied to an audible arcing alarm illustrated as a speaker.

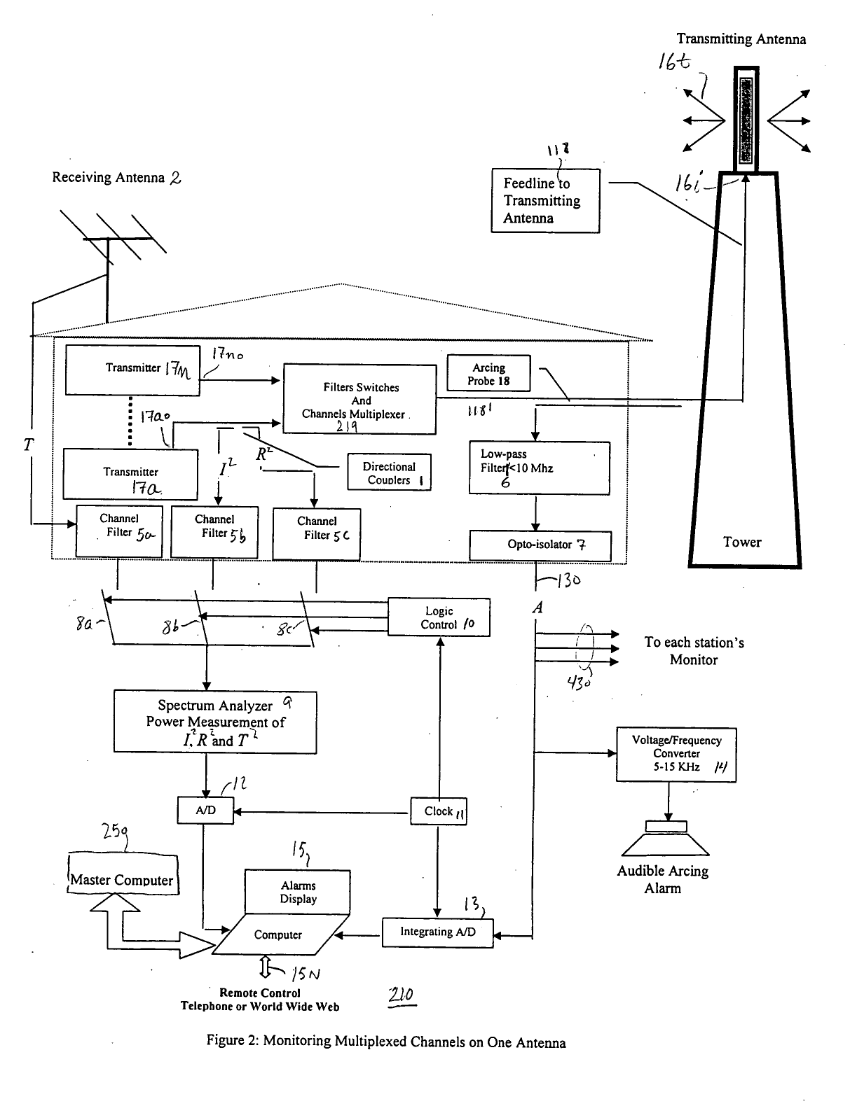

The arrangement of FIG. 1 was described as being a single-channel system, but some antennas are multiplexed to transmit signals simultaneously on a plurality of channels. According to an aspect of the invention, a broadband arc sensing arrangement is used in the context of a multiplexed system. In FIG. 2, elements corresponding to those of FIG. 1 are designated by like reference alphanumerics. A multichannel transmitting system 210 of FIG. 2 is generally similar to system 110 of FIG. 1. Unlike the arrangement of FIG. 1, system 210 includes a plurality of transmitters, two of which are illustrated as 17a and 17n. Transmitter 17a is connected in a manner similar to that of transmitter 17a of FIG. 1, in that its output port 17a is connected to directional couplers 1, and its output signal is coupled by way of a filter and switch arrangement to transmission line 118. However, in the arrangement of FIG. 2, the filter and switch arrangement, illustrated as a block 219, receives input signals from a plurality of other transmitters, including transmitter 17n. The incident power I and reflected power R associated with transmitter 17a are coupled by directional coupler(s) 1 to channel filters 5b and 5c as in FIG. 1, and the transmissions of transmitter 17a are monitored by switches 8a, 8b, and 8c controlled by logic block 10. It should be noted that the voltages proportional to the incident power and reflected power are channel-specific, and as a result the coupler 1 must be located between each transmitter and the multiplexer 219. Spectrum analyzer 9 produces amplitude-representative signals, and a channel computer 15 produces alarm signals associated with the channel of transmitter 17a.

In the arrangement of FIG. 2, each transmitter is associated with a monitoring arrangement including a set of channel filters corresponding to 5a, 5b, and 5c, a switching arrangement corresponding to 8a, 8b, 8c, control logic corresponding to 10, power measuring arrangement corresponding to spectrum analyzer 9, and integrating A/D 13. The clock 11 may be individual or common to all the monitoring arrangements.

In the arrangement of FIG. 2, the receiving antenna 2 may be replicated for receiving transmitted signals in each channel, or a broadband antenna may be used, with separate splitting filters corresponding to filter 5a for separating the signals by channel.

The arc sensing probe 3 of FIGS. 1 and 4 is not useful in the broadband context of FIG. 2, because the wavelength-dependent lengths of the transmission line portions of the shunt transmission line are inherently narrowband, and when tuned for any particular channel might adversely affect the other channels. For this reason, a broadband arc sensing probe 18 is coupled to transmission line 118 for producing analog signals representative of arcing. The broadband arc sensing probe 18 is located in the feed transmission line “between” the antenna 16 and the multiplexer 219 for reason that the arc signals will not propagate through the multiplexer 219. If there is a possibility that arcs might occur between the transmitter 17a and the multiplexer, additional arc sensing probes may be needed. The signals representative of arcing are the same in either the single-channel or multiple-channel case, as arcing is not channelized.

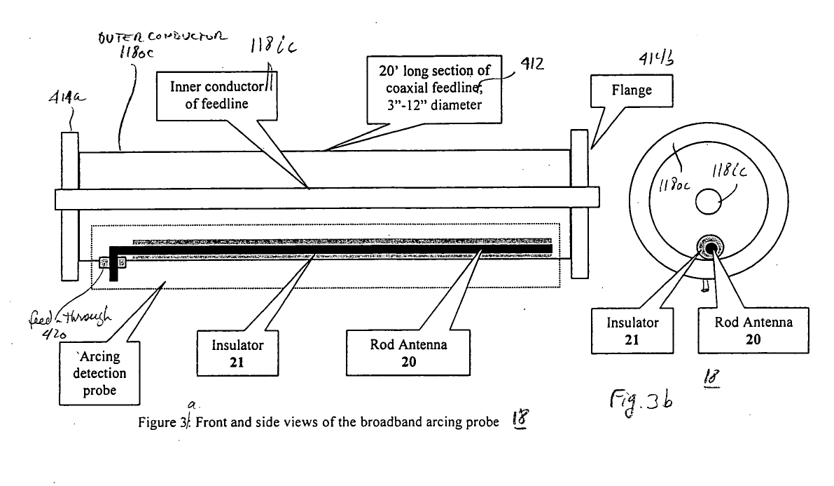

The arc sensing probe 18 of FIGS. 2 and 3a, 3b includes a coaxial transmission line section 412, which may have a conventional section length of 20 feet, and which includes an inner conductor 118ic, an outer conductor 118oc, and a pair of end flanges 414a and 414b for mating with other sections or with system ports. An electrically conductive rod antenna 20 extends physically parallel with the center conductor 118ic in a manner which does not electrically contact either the center conductor 118ic or the outer conductor 118oc. In the arrangement of FIGS. 3a and 3b, electrical isolation is provided by a dielectric sleeve or insulator 21 extending over the length of conductive rod antenna 20. The dielectric sleeve 21 may be adhesively attached to the interior surface of outer conductor 118oc and to the rod antenna to hold the arc sensing portions in position. Voltages resulting from arcs are induced or appear in the rod antenna 20. The left end, as illustrated in FIG. 3a, of rod antenna 20 is coupled by way of a feedthrough connector 420 to a location outside the outer conductor 118oc, so the arc representative signal can be made available to low-pass filter 6 of FIG. 2. The arc-representative low-pass filtered (that is, the low-frequency components among those induced in rod antenna 20) signal is applied by way of opto-isolator 7 to path 130. The arc representative signal is applied to integrating A/D 13 of the monitor for the channel associated with transmitter 17a, and by way of a set of additional paths designated 430 to the corresponding A/D of the monitors for the channels associated with the other transmitters including transmitter 17n. Processing takes place in each of the channel monitors as described in conjunction with FIG. 1.

The individual channel monitors for each of the transmitters 17a, . . . , 17n of FIG. 2 sense incident, reflected, and transmitted power for only the one channel for which they are tuned. The arcing detector, however, may be common to all the channels, since the arc signals are at frequencies below any TV or FM channel. In the case of multiple channels and multiple antennas all at the same site, the local computer would communicate with a master computer, such as 250 of FIG. 2. Such a master computer is necessary in order to monitor the power radiated from each antenna and each channel and to provide go/no-go decision before climbing on the tower for repair or maintenance. Thus, according to an aspect of the invention, the individual channel monitor computers, such as computer 15 of FIG. 2, are interconnected with a master computer 250, which monitors all the single-channel monitors and the arc detector for controlling the transmitter when a failure in a particular channel is recognized, and for generating the signals or alarms which indicate when personnel may approach the antenna or other high power equipment. The system and apparatus comprising the present invention allows for simultaneous local and remote computer control. The remote control, whether via telephone, wireless or through the World Wide Web, can be established by using commercially available components and software.

Thus, in general, a computer-controlled or computerized monitoring apparatus processes measurements of four signals: power transmitted to the antenna I², power reflected from the antenna R², power radiated from the antenna T² and arc voltage A that would be reflected back and forth between the antenna and the transmitter. The monitor provides early warning alarms of arcing or overheating in the feedlines to the antenna and inside the antenna long before a catastrophic failure has occurred and the transmitter is forced to shut down by its own protective circuit. Early warning of developing failures allows for orderly transition to standby transmission facilities and for timely maintenance without losing on-air time in the event of catastrophic failure. The monitoring apparatus also provides a failsafe indication of whether or not power is delivered to the antenna and whether or not the antenna radiates the power delivered to it. Such failsafe indication is required before maintenance personnel are allowed near the antenna. The apparatus described here measures the relative power density at specified locations near and on the tower and compares the measured RFR exposure density to that allowable by the Federal Communications Commission (FCC). The monitoring apparatus can be applied to multiple transmitters with multiple channel combiners feeding a common antenna connected to the transmitters with one or two feedlines.

It should be noted that the antenna may itself include one or more internal transmission lines, which are subject to the same problems as the feed transmission line 118 of FIG. 1 or 2. The monitor according to the invention should respond to such transmission line problems.

While the single-channel system described in conjunction with FIG. 1 has a narrowband arc sensing probe 3, the broadband arc sensing probe 18 may be used in the narrowband context. While the receiving antenna 2 of FIGS. 1 and 2 has been described as a consumer-grade antenna, it may of course be a commercial or other-grade antenna. The computers of FIGS. 1 and 2 may be configured for remote control by means of conventional software to connect by way of land or wireless telephone, or by way of the World Wide Web to remote locations.

A method according to an aspect of the invention for transmitter (17a) control in an electromagnetic wave transmitting system (110) which includes a transmitter (17a) coupled by a first transmission line (118) to an antenna (16) comprises the steps of sensing the presence of arcing in the first transmission line (118) and generating a signal (A) in the presence of the arcing. The method also includes the step of reducing the power transmitted by the transmitter (17a) in the presence of the signal (A). The method may also include the step of transmitting signal from the transmitter (17a) toward the antenna (16) through the transmission line (118) within a predetermined frequency band, in which case the step of sensing the presence of arcing in the first transmission line (118) includes the step of low-pass filtering (6) signal appearing on the transmission line (118), to thereby block signals within the predetermined frequency band and to pass only frequencies lower than those of the predetermined frequency band. In a particularly advantageous mode of this aspect of the invention, the step of sensing the presence of arcing and generating a signal includes the steps of determining the ratios of K₀ and K(t), where

$${K}_{0} = {( \frac{{R}_{0}}{{T}_{0}} )}^{2} and K ( t ) = {( \frac{R ( t )}{T ( t )} )}^{2} \qquad ( 2 )$$

are the ratios during normal operation and during a failure in progress, respectively, and wherein
R₀ is the reflected signal voltage during normal operation;
R(t) is the reflected signal voltage during a failure in progress;
T₀ is the transmitted signal voltage during normal operation; and
T(t) is the transmitted signal voltage during a failure in progress. The step of generating a signal also includes the step of generating an alarm signal if

$$\frac{K ( t )}{{K}_{0}} 〉 1. \qquad ( 3 )$$

According to another aspect of the invention, a method for failure detection in an electromagnetic wave transmitting system (110) which includes a transmitter (17a) coupled by a first transmission line (118) to an antenna (16) comprises the steps of sensing the radiated power from the antenna (16) by use of a receiving antenna (2), and comparing with a standard representative of proper operation of the transmitting system at least one of (a) the received radiated power (R²) and (b) the ratio of incident to reflected power (T/R)², to thereby generate a first signal. Arcing in the first transmission line (118) is sensed and a second signal (A) is generated in the presence of arcing. A failure-indicative signal is generated in the presence of at least one of the first and second signals. In this other aspect of the invention, the step of sensing arcing in the transmission line (118) may include the steps of coupling a first end (124_{fe}) of a second transmission line (124) in electrical parallel or shunt with the first transmission line (118), where the second transmission line (124) is one of short-circuited (124_{sc}) and open-circuited (124oc) at that end (124ᵣₑ) remote from the first end (124_{fe}). The second transmission line (118) may define a tap (124ₜ) at a location which is an integer number (1 in the illustrated case) of half-wavelengths from that end (124ᵣₑ) remote from the first end (124_{fe}) in the case of a short-circuit termination (124_{sc}) and an odd integer number of quarter-wavelengths from that end (124ᵣₑ) remote from the first end (124_{fe}) in the case of an open-circuit termination. In this other aspect of the invention, the transmission line (118) may be an unbalanced transmission line (coaxial) including an elongated conductor (118_{ic}) having a given surface area and a second conductor (118_{ic}) having a surface area larger than the given surface area; the step of sensing arcing in the transmission line (118) in this case may include the steps of extending an insulated (21) conductor (20) physically parallel with the elongated (118_{ic}) and second (118_{oc}) conductors and spaced therefrom, and coupling voltage (420) appearing on the insulated conductor (20, 21) to a location outside the transmission line (118).

According to yet another aspect of the invention, an apparatus (110, 210) includes an antenna (16) for one of television and FM, with the antenna (16) including an unbalanced transmission-line input port (16i), and a source of transmitter (17a) power for the one of television and FM. An unbalanced feed transmission-line (118) is coupled to the input port (16i) of the antenna (16), for coupling power originating from the source (17a) to the antenna (16) for generating electromagnetic radiation (16t) therefrom. A receiving antenna (2) is provided for receiving the electromagnetic radiation, and for generating an analog signal (T²) indicative of the power transmitted by the antenna (16). A directional coupling arrangement (1) is coupled to the feed transmission-line (118) for generating analog signals indicative of signal power (12) incident on the feed transmission line (118) from the source (17a) and of reflected power (R²) reflected from the antenna (16) toward the source (17a). A power measurement arrangement (8a, 8b, 8c, 9, and 10) is coupled to receive the analog signals indicative of transmitted, incident, and reflected signal, for generating analog signals representative of transmitted, incident, and reflected power, respectively. An analog-to-digital conversion arrangement (12) is coupled to receive analog signals representative of transmitted, incident, and reflected power, for converting the analog signals into digital signals representative of measured transmitted, incident, and reflected power. A processing arrangement (15) is coupled to receive the digital signals, and for comparing the measured transmitted, incident, and reflected power with stored reference values of the transmitted, incident, and reflected power, and for generating alarm signals in response, which may be monotonic response, to deviation of the measured power relative to or with respect to the reference values. This apparatus (110, 210) may include filtering means (5a, 5b, 5c) for filtering the analog signals. It may also include a switching arrangement (8a, 8b, 8c, 10) coupled to the receiving antenna (16), to the directional coupling arrangement (1), and to the analog-to-digital conversion arrangement (12), for sequentially switching the analog signals representing transmitted signal, incident signal, and reflected signal to the analog-to-digital conversion means (12) in the form of pulse-amplitude-modulated (PAM) signals. The processing arrangement (15) may comprise a network connection arrangement (15N) for providing remote control of the processing means by way of at least one of (a) landline telephone, (b) wireless telephone, and (c) World Wide Web.

A method according to a yet further aspect of the invention for transmitter (17a) control in an electromagnetic wave transmitting system (110), which transmitting system (110) includes a transmitter (17a) coupled by a first transmission line (118) to an antenna (16), comprises the steps of, during normal operation, determining the signal voltage or amplitude reflected from the antenna (16) toward the transmitter (17a) in the first transmission line (118) and the transmitted signal (16t) amplitude or voltage, and storing (in computer 15) information (in the form of power) relating to the normal-operation reflected and transmitted signal voltage or amplitude. The current signal voltage reflected from the antenna (16) toward the transmitter (17a) in the first transmission line (118), and the transmitted signal amplitude, are monitored, to thereby form current reflected and transmitted signal voltage or amplitude information. A constant K₀ is determined by squaring the quotient of the normal-operation reflected signal voltage divided by the normal-operation transmitted signal amplitude. A further constant K(t) is determined by squaring the quotient of the current reflected signal voltage divided by the current transmitted signal amplitude. The presence of arcing in the first transmission line is sensed or determined by taking the ratio of K(t) divided by K₀, and deeming arcing to be present if

$$\frac{K ( t )}{{K}_{0}} 〉 1.$$

In a preferred version of this aspect of the invention, an alarm signal is generated (at computer 15 or at a remote site) when arcing is deemed to be present.

A method for exposure control in a system (210) of plural transmitting antennas (16) fed by transmission lines (118) according to another aspect of the invention comprises the steps of sensing the transmitted power from each of the antennas to produce individual antenna powers, and summing the individual antenna powers to produce a summed-transmitted-power signal. The method also includes the step of measuring incident power flowing in the transmission lines to each of the antennas, and summing the incident power for each of the antennas to produce a summed incident power signal. Climbing on any of the antennas is prohibited so long as one of the summed-transmitted-power signal and the summed incident power signal has a value exceeding zero.

A method for exposure control in an electromagnetic transmitter arrangement (110) according to a further aspect of the invention includes the steps of sensing transmitted signal voltage during normal operation and sensing the current transmitted voltage, and squaring the ratio of the current transmitted voltage divided by the normal-operation signal voltage to produce a calculated result. This method also includes the comparing of the calculated result with the FCC allowable RFR exposure limit, and setting an exposure alarm if the calculated result exceeds the allowable FCC RFR exposure limit.

1. A method for transmitter control in an electromagnetic wave transmitting system including a transmitter coupled by a first transmission line to an antenna, said method comprising the steps of:
sensing the presence of arcing in said first transmission line, and generating a signal in the presence of said arcing; and
reducing the power transmitted by said transmitter in the presence of said signal.

2. A method according to claim 1, further comprising the step of:
transmitting signal from said transmitter toward said antenna through said transmission line within a predetermined frequency band; and wherein
said step of sensing the presence of arcing in said first transmission line includes the step of low-pass filtering signal appearing on said transmission line to thereby block signals within said predetermined frequency band and to pass only frequencies lower than those of said predetermined frequency band.

3. A method according to claim 1, wherein said step of sensing the presence of arcing and generating a signal includes the steps of determining the ratios of K₀ and K(t), where
$${K}_{0} = {( \frac{{R}_{0}}{{T}_{0}} )}^{2} and K ( t ) = {( \frac{R ( t )}{T ( t )} )}^{2} \qquad ( 2 )$$
are the ratios during normal operation and during a failure in progress, respectively, and
wherein
R₀ is the reflected signal voltage during normal operation;
R(t) is the reflected signal voltage during a failure in progress;
T₀ is the transmitted signal voltage during normal operation; and
T(t) is the transmitted signal voltage during a failure in progress; and
said step of generating a signal includes the step of generating an alarm signal if
$$\frac{K ( t )}{{K}_{0}} 〉 1. \qquad ( 3 )$$

4. A method for failure detection in an electromagnetic wave transmitting system including a transmitter coupled by a first transmission line to an antenna, said method comprising the steps of:
sensing the radiated power from said antenna by use of a receiving antenna;
comparing with a standard representative of proper operation of said transmitting system at least one of (a) the received radiated power and (b) the ratio of incident to reflected power, to thereby generate a first signal;
sensing arcing in said first transmission line and generating a second signal in the presence of arcing; and
generating a failure-indicative signal in the presence of at least one of said first and second signals.

5. A method according to claim 4, wherein said step of sensing arcing in said transmission line includes the steps of:
coupling a first end of a second transmission line in electrical parallel with said first transmission line, said second transmission line being one of short-circuited and open-circuited at that end remote from said first end.

6. A method according to claim 5, wherein said second transmission line defines a tap at a location which is located an integer number of half-wavelengths from that end remote from said first end in the case of a short-circuit termination and an odd integer number of quarter-wavelengths from that end remote from said first end in the case of an open-circuit termination.

7. A method according to claim 4, wherein said transmission line is an unbalanced transmission line including an elongated conductor having a given surface area and a second conductor having a surface area larger than said given surface area; and wherein:
said step of sensing arcing in said transmission line includes the steps of extending an insulated conductor physically parallel with said elongated and second conductors and spaced therefrom; and
coupling voltage appearing on said insulated conductor to a location outside said transmission line.

8. An apparatus, comprising:
an antenna for one of television and FM, said antenna including an unbalanced transmission-line input port;
a source of transmitter power for said one of television and FM;
an unbalanced feed transmission-line coupled to said input port of said antenna, for coupling power originating from said source to said antenna for generating electromagnetic radiation therefrom;
a receiving antenna for receiving said electromagnetic radiation, for generating an analog signal indicative of the power transmitted by said antenna;
directional coupling means coupled to said feed transmission-line, for generating analog signals indicative of signal power incident on said feed transmission line from said source and of reflected power reflected from said antenna toward said source;
power measurement means coupled to receive said analog signals indicative of transmitted, incident, and reflected power, for generating analog signals representative of transmitted, incident, and reflected power, respectively;
analog-to-digital conversion means coupled to receive analog signals representative of transmitted, incident, and reflected power, for converting said analog signals into digital signals representative of measured transmitted, incident, and reflected power; and
processing means coupled to receive said digital signals, and for comparing said measured transmitted, incident, and reflected power with stored reference values of said transmitted, incident, and reflected power, and for generating alarm signals in monotonic response to deviation of said measured power with said reference values.

9. An apparatus according to claim 8, further comprising filtering means for filtering said analog signals.

10. An apparatus according to claim 8, further comprising switching means coupled to said receiving antenna, to said directional coupling means, and to said analog-to-digital conversion means, for sequentially switching said analog signals representing transmitted power, incident power, and reflected power to said analog-to-digital conversion means in the form of pulse-amplitude-modulated signals.

11. An apparatus according to claim 8, wherein said processing means comprises network connection means for providing remote control of said processing means by way of at least one of (a) landline telephone, (b) wireless telephone, and (c) World Wide Web.

12. A method for transmitter control in an electromagnetic wave transmitting system including a transmitter coupled by a first transmission line to an antenna, said method comprising the steps of:
during normal operation, determining the signal voltage reflected from said antenna toward said transmitter in said first transmission line and the transmitted signal amplitude, and storing information relating to said signal voltage and amplitude;
monitoring the current signal voltage reflected from said antenna toward said transmitter in said first transmission line and the transmitted signal amplitude to thereby form current signal voltage and amplitude information;
determining constant K₀ by squaring the quotient of the normal-operation reflected signal voltage divided by the normal-operation transmitted signal amplitude;
determining constant K(t) by squaring the quotient of the current reflected signal voltage divided by the current transmitted signal amplitude;
sensing the presence of arcing in said first transmission line by taking the ratio of K(t) divided by K₀, and deeming arcing to be present if
$$\frac{K ( t )}{{K}_{0}} 〉 1 ;$$
and
generating an alarm signal when said arcing is deemed to be present.

13. A method for exposure control in a system of plural transmitting antennas fed by transmission lines, said method comprising the steps of:
sensing the transmitted power from each of said antennas to produce individual antenna powers;
summing said individual antenna powers to produce a summed-transmitted-power signal;
measuring incident power flowing in said transmission lines to each of said antennas;
summing said incident power for each of said antennas to produce a summed incident power signal; and
prohibiting climbing on any of said antennas so long as one of said summed-transmitted-power signal and said summed incident power signal has a value exceeding zero.

14. A method for exposure control in an electromagnetic transmitter arrangement, said method comprising the steps of:
sensing transmitted signal voltage during normal operation;
sensing the current transmitted voltage;
squaring the ratio of the current transmitted voltage divided by the normal-operation signal voltage to produce a calculated result;
comparing the calculated result with the FCC RFR exposure limit allowable limit; and
setting an exposure alarm if the calculated result exceeds the FCC allowable RFR exposure limit.
